(19) United States
(12) Patent Application Publication
(10) Pub. No.: US 2024/0204005 A1
(43) Pub. Date: Jun. 20, 2024

(54) TRANSISTORS WITH DIELECTRIC STACK ISOLATING BACKSIDE POWER RAIL

(71) Applicant: International Business Machines Corporation, Armonk, NY (US)

(72) Inventors: Tao Li, Slingerlands, NY (US); Sagarika Mukesh, Albany, NY (US); Julien Frougier, Albany, NY (US); Nicolas Jean Loubet, Guilderland, NY (US); Ruilong Xie, Niskayuna, NY (US)

(21) Appl. No.: 18/080,828

(22) Filed: Dec. 14, 2022

(51) Int. Cl. H01L 27/12

(52) U.S. Cl. CPC H01L 27/124; H01L 27/1266

(57) ABSTRACT

A semiconductor structure includes a frontside source/drain region, and a dielectric stack disposed on a bottom surface of the frontside source/drain region. The dielectric stack includes a first dielectric layer and a second dielectric layer.

### BACKGROUND

A field-effect transistor (FET) is a transistor having a source, a gate, and a drain, the operation of which depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

### SUMMARY

Illustrative embodiments of the present application include techniques for use in semiconductor manufacture. In an illustrative embodiment, a semiconductor structure includes a frontside source/drain region, and a dielectric stack disposed on a bottom surface of the frontside source/drain region. The dielectric stack includes a first dielectric layer and a second dielectric layer.

The semiconductor structure of the illustrative embodiment advantageously allows for formation of a dielectric stack that isolates one or more of a source/drain region and a gate from a backside power rail for a backside power delivery network. The backside power delivery network brings a power line from the back-end-of-line to the backside of the semiconductor structure to release the congestion of the power line at the frontside back-end-of-line and therefore allows for improved routing capability for both backside and frontside.

In one or more additional illustrative embodiments, as may be combined with the preceding paragraphs, the semiconductor structure further includes a backside power rail disposed on the dielectric stack and separated from the frontside source/drain region.

In one or more additional illustrative embodiments, as may be combined with the preceding paragraphs, the semiconductor structure further includes a via-to-backside power rail connected to the backside power rail.

In one or more additional illustrative embodiments, as may be combined with the preceding paragraphs, the backside power rail is connected to the via-to-backside power rail from a backside of the semiconductor structure.

In one or more additional illustrative embodiments, as may be combined with the preceding paragraphs, the via-to-backside power rail includes a lower portion located on the backside power rail and an upper portion located on a sidewall of the frontside source/drain region.

In one or more additional illustrative embodiments, as may be combined with the preceding paragraphs, the lower portion of the via-to-backside power rail includes a step-wise configuration.

In one or more additional illustrative embodiments, as may be combined with the preceding paragraphs, the semiconductor structure further includes a frontside source/drain contact disposed on the frontside source/drain region, wherein the frontside source/drain contact is connected to the backside power rail by a via-to-backside power rail.

In one or more additional illustrative embodiments, as may be combined with the preceding paragraphs, the semiconductor structure is part of a backside power delivery network.

In one or more additional illustrative embodiments, as may be combined with the preceding paragraphs, the first dielectric layer includes a first dielectric material and the second dielectric layer includes a second dielectric material different from the first dielectric material.

In another illustrative embodiment, a semiconductor structure includes a dielectric stack disposed on a bottom surface of at least one frontside gate; and a backside power rail disposed on the dielectric stack and separated from the at least one frontside gate. The dielectric stack includes a first dielectric layer and a second dielectric layer.

The semiconductor structure of the illustrative embodiment advantageously allows for formation of a dielectric stack that isolates one or more of a source/drain region and a gate from a backside power rail for a backside power delivery network. The backside power delivery network brings a power line from the back-end-of-line to the backside of the semiconductor structure to release the congestion of the power line at the frontside back-end-of-line and therefore allows for improved routing capability for both backside and frontside.

In one or more additional illustrative embodiments, as may be combined with the preceding paragraphs, the at least one frontside gate includes a first frontside gate and a second frontside gate.

In one or more additional illustrative embodiments, as may be combined with the preceding paragraphs, the first frontside gate is part of a first nanosheet channel and the second frontside gate is part of a second nanosheet channel separated from the first nanosheet channel by a dielectric pillar.

In one or more additional illustrative embodiments, as may be combined with the preceding paragraphs, the semiconductor structure further includes a via-to-backside power rail disposed on the backside power rail.

In one or more additional illustrative embodiments, as may be combined with the preceding paragraphs, the first dielectric layer includes a first dielectric material and the second dielectric layer includes a second dielectric material different from the first dielectric material.

In yet another illustrative embodiment, a semiconductor structure includes a first dielectric stack disposed on a bottom surface of a first frontside source/drain region, a first frontside source/drain contact disposed on a top surface of the first frontside source/drain region, a backside power rail disposed on the first dielectric stack and separated from the first frontside source/drain region, and a via-to-backside power rail disposed on a sidewall of the first frontside source/drain region to connect the backside power rail to the first frontside source/drain contact. The first dielectric stack includes a first dielectric layer and a second dielectric layer.

The semiconductor structure of the illustrative embodiment advantageously allows for formation of a dielectric stack that isolates one or more of a source/drain region and a gate from a backside power rail for a backside power delivery network. The backside power delivery network brings a power line from the back-end-of-line to the backside of the semiconductor structure to release the congestion of the power line at the frontside back-end-of-line and therefore allows for improved routing capability for both backside and frontside.

In one or more additional illustrative embodiments, as may be combined with the preceding paragraphs, the semiconductor structure further includes a second frontside source/drain region adjacent the first frontside source/drain region, a second dielectric stack disposed on a bottom surface of the second frontside source/drain region and on a top surface of the backside power rail, and a second frontside source/drain contact disposed on a top surface of the second frontside source/drain region. The second dielectric stack includes a first dielectric layer and a second dielectric layer.

In one or more additional illustrative embodiments, as may be combined with the preceding paragraphs, the via-to-backside power rail includes a lower portion located on the backside power rail and an upper portion located on the sidewall of the first frontside source/drain region.

In one or more additional illustrative embodiments, as may be combined with the preceding paragraphs, the lower portion of the via-to-backside power rail includes a step-wise configuration.

In one or more additional illustrative embodiments, as may be combined with the preceding paragraphs, the first dielectric layer includes a first dielectric material and the second dielectric layer includes a second dielectric material different from the first dielectric material.

In still yet another illustrative embodiment, a semiconductor structure includes a backside source/drain contact disposed on a bottom surface of a first frontside source/drain, a backside power rail disposed on the backside source/drain contact and separated from the first frontside source/drain region, a second frontside source/drain region adjacent the first frontside source/drain region, and a dielectric stack disposed on a bottom surface of the second frontside source/drain region. The dielectric stack includes a first dielectric layer and a second dielectric layer.

The semiconductor structure of the illustrative embodiment advantageously allows for formation of a dielectric stack that isolates one or more of a source/drain region and a gate from a backside power rail for a backside power delivery network. The backside power delivery network brings a power line from the back-end-of-line to the backside of the semiconductor structure to release the congestion of the power line at the frontside back-end-of-line and therefore allows for improved routing capability for both backside and frontside.

In one or more additional illustrative embodiments, as may be combined with the preceding paragraphs, the backside power rail is connected to the backside source/drain contact from a backside of the semiconductor structure.

In one or more additional illustrative embodiments, as may be combined with the preceding paragraphs, an upper surface of the backside source/drain contact has a step-wise configuration comprising a top portion in contact with the first source/drain region and a bottom portion extending between the first frontside source/drain region and the second frontside source/drain region.

In one or more additional illustrative embodiments, as may be combined with the preceding paragraphs, the semiconductor structure further includes a frontside source/drain contact disposed on a top surface of the second frontside source/drain region.

In one or more additional illustrative embodiments, as may be combined with the preceding paragraphs, the first dielectric layer includes a first dielectric material and the second dielectric layer includes a second dielectric material different from the first dielectric material.

In still a further illustrative embodiment, a semiconductor device includes a first nanosheet field effect transistor device comprising a first nanosheet stack, a first gate and a first source/drain region, and a second nanosheet field effect transistor device adjacent to the first nanosheet field effect transistor device. The second nanosheet field effect transistor device includes a second nanosheet stack, a second gate and a second source/drain region. The semiconductor device further includes a first dielectric stack disposed on a bottom surface of the first nanosheet field effect transistor device, a second dielectric stack disposed on a bottom surface of the second nanosheet field effect transistor device, a shallow trench isolation region disposed between first dielectric stack and the second dielectric stack, and a backside power rail disposed on the first dielectric stack, the second dielectric stack and the shallow trench isolation region and separated from the first nanosheet field effect transistor device and the second nanosheet field effect transistor device. Each of the first dielectric stack and the second dielectric stack includes a first dielectric layer and a second dielectric layer.

The semiconductor device of the illustrative embodiment advantageously allows for formation of a dielectric stack that isolates one or more of a source/drain region and a gate from a backside power rail for a backside power delivery network. The backside power delivery network brings a power line from the back-end-of-line to the backside of the semiconductor structure to release the congestion of the power line at the frontside back-end-of-line and therefore allows for improved routing capability for both backside and frontside.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a cross-sectional view illustrating a semiconductor structure for use at a first-intermediate fabrication stage, according to an illustrative embodiment.

FIG. 2 is a cross-sectional view of the semiconductor structure at a second-intermediate fabrication stage, according to an illustrative embodiment.

FIG. 3 is a cross-sectional view illustrating the semiconductor structure at a third-intermediate fabrication stage, according to an illustrative embodiment.

FIG. 4 is a cross-sectional view illustrating the semiconductor structure at a fourth-intermediate fabrication stage, according to an illustrative embodiment.

FIG. 5 is a cross-sectional view illustrating the semiconductor structure at a fifth-intermediate fabrication stage, according to an illustrative embodiment.

FIG. 6 is a cross-sectional view illustrating the semiconductor structure at a sixth-intermediate fabrication stage, according to an illustrative embodiment.

FIG. 7 is a cross-sectional view illustrating the semiconductor structure at a seventh-intermediate fabrication stage, according to an illustrative embodiment.

FIG. 8 is a cross-sectional view illustrating the semiconductor structure at an eighth-intermediate fabrication stage, according to an illustrative embodiment.

FIG. 9 is a cross-sectional view illustrating the semiconductor structure at a ninth-intermediate fabrication stage, according to an illustrative embodiment.

FIG. 10 is a cross-sectional view illustrating the semiconductor structure at a tenth-intermediate fabrication stage, according to an illustrative embodiment.

FIG. 11 is a cross-sectional view illustrating the semiconductor structure at an eleventh-intermediate fabrication stage, according to an illustrative embodiment.

FIG. 12 is a cross-sectional view illustrating the semiconductor structure at a twelfth-intermediate fabrication stage, according to an illustrative embodiment.

FIG. 13 is a cross-sectional view illustrating the semiconductor structure at a thirteenth-intermediate fabrication stage, according to an illustrative embodiment.

FIG. 14 is a cross-sectional view illustrating the semiconductor structure at a fourteenth-intermediate fabrication stage, according to an illustrative embodiment.

FIG. 15 is a cross-sectional view illustrating the semiconductor structure at a fifteenth-intermediate fabrication stage, according to an illustrative embodiment.

FIG. 16 is a cross-sectional view illustrating the semiconductor structure at a sixteenth-intermediate fabrication stage, according to an illustrative embodiment.

FIG. 17 is a cross-sectional view illustrating the semiconductor structure at a seventeenth-intermediate fabrication stage, according to an illustrative embodiment.

FIG. 18A is a top view illustrating the semiconductor structure at an eighteenth-intermediate fabrication stage, according to an illustrative embodiment.

FIG. 18B is a cross-sectional view illustrating the semiconductor structure taken along the Y1-Y1 axis of FIG. 18A at the eighteenth-intermediate fabrication stage, according to an illustrative embodiment.

FIG. 19A is a cross-sectional view of the semiconductor structure taken along the X-X axis of FIG. 18A at a nineteenth-intermediate fabrication stage, according to an illustrative embodiment.

FIG. 19B is a cross-sectional view of the semiconductor structure taken along the Y1-Y1 axis of FIG. 18A at the nineteenth-intermediate fabrication stage, according to an illustrative embodiment.

FIG. 19C is a cross-sectional view of the semiconductor structure taken along the Y2-Y2 axis of FIG. 18A at the nineteenth-intermediate fabrication stage, according to an illustrative embodiment.

FIG. 20A is a top view illustrating the semiconductor structure at a twentieth-intermediate fabrication stage, according to an illustrative embodiment.

FIG. 20B is a cross-sectional view of the semiconductor structure taken along the X-X axis of FIG. 20A at the twentieth-intermediate fabrication stage, according to an illustrative embodiment.

FIG. 20C is a cross-sectional view of the semiconductor structure taken along the Y1-Y1 axis of FIG. 20A at the twentieth-intermediate fabrication stage, according to an illustrative embodiment.

FIG. 20D is a cross-sectional view of the semiconductor structure taken along the Y2-Y2 axis of FIG. 20A at the twentieth-intermediate fabrication stage, according to an illustrative embodiment.

FIG. 21A is a top view illustrating the semiconductor structure at a twenty-first-intermediate fabrication stage, according to an illustrative embodiment.

FIG. 21B is a cross-sectional view of the semiconductor structure taken along the X-X axis of FIG. 21A at the twenty-first-intermediate fabrication stage, according to an illustrative embodiment.

FIG. 21C is a cross-sectional view of the semiconductor structure taken along the Y1-Y1 axis of FIG. 21A at the twenty-first-intermediate fabrication stage, according to an illustrative embodiment.

FIG. 21D is a cross-sectional view of the semiconductor structure taken along the Y2-Y2 axis of FIG. 21A at the twenty-first-intermediate fabrication stage, according to an illustrative embodiment.

FIG. 22A is a cross-sectional view of the semiconductor structure taken along the X-X axis of FIG. 21A at a twenty-second-intermediate fabrication stage, according to an illustrative embodiment.

FIG. 22B is a cross-sectional view of the semiconductor structure taken along the Y1-Y1 axis of FIG. 21A at the twenty-second-intermediate fabrication stage, according to an illustrative embodiment.

FIG. 22C is a cross-sectional view of the semiconductor structure taken along the Y2-Y2 axis of FIG. 21A at the twenty-second-intermediate fabrication stage, according to an illustrative embodiment.

FIG. 23A is a cross-sectional view of the semiconductor structure taken along the X-X axis of FIG. 21A at a twenty-third-intermediate fabrication stage, according to an illustrative embodiment.

FIG. 23B is a cross-sectional view of the semiconductor structure taken along the Y1-Y1 axis of FIG. 21A at the twenty-third-intermediate fabrication stage, according to an illustrative embodiment.

FIG. 23C is a cross-sectional view of the semiconductor structure taken along the Y2-Y2 axis of FIG. 21A at the twenty-third-intermediate fabrication stage, according to an illustrative embodiment.

FIG. 24A is a cross-sectional view of the semiconductor structure taken along the X-X axis of FIG. 21A at a twenty-fourth-intermediate fabrication stage, according to an illustrative embodiment.

FIG. 24B is a cross-sectional view of the semiconductor structure taken along the Y1-Y1 axis of FIG. 21A at the twenty-fourth-intermediate fabrication stage, according to an illustrative embodiment.

FIG. 24C is a cross-sectional view of the semiconductor structure taken along the Y2-Y2 axis of FIG. 21A at the twenty-fourth-intermediate fabrication stage, according to an illustrative embodiment.

FIG. 25A is a cross-sectional view of the semiconductor structure taken along the X-X axis of FIG. 21A at a twenty-fifth-intermediate fabrication stage, according to an illustrative embodiment.

FIG. 25B is a cross-sectional view of the semiconductor structure taken along the Y1-Y1 axis of FIG. 21A at the twenty-fifth-intermediate fabrication stage, according to an illustrative embodiment.

FIG. 25C is a cross-sectional view of the semiconductor structure taken along the Y2-Y2 axis of FIG. 21A at the twenty-fifth-intermediate fabrication stage, according to an illustrative embodiment.

FIG. 26A is a cross-sectional view of the semiconductor structure taken along the X-X axis of FIG. 21A at a twenty-sixth-intermediate fabrication stage, according to an illustrative embodiment.

FIG. 26B is a cross-sectional view of the semiconductor structure taken along the Y1-Y1 axis of FIG. 21A at the twenty-sixth-intermediate fabrication stage, according to an illustrative embodiment.

FIG. 26C is a cross-sectional view of the semiconductor structure taken along the Y2-Y2 axis of FIG. 21A at the twenty-sixth-intermediate fabrication stage, according to an illustrative embodiment.

FIG. 27A is a cross-sectional view of the semiconductor structure taken along the X-X axis of FIG. 21A at a twenty-seventh-intermediate fabrication stage, according to an illustrative embodiment.

FIG. 27B is a cross-sectional view of the semiconductor structure taken along the Y1-Y1 axis of FIG. 21A at the twenty-seventh-intermediate fabrication stage, according to an illustrative embodiment.

FIG. 27C is a cross-sectional view of the semiconductor structure taken along the Y2-Y2 axis of FIG. 21A at the twenty-seventh-intermediate fabrication stage, according to an illustrative embodiment.

FIG. 28A is a cross-sectional view of the semiconductor structure taken along the X-X axis of FIG. 21A at a twenty-eighth-intermediate fabrication stage, according to an illustrative embodiment.

FIG. 28B is a cross-sectional view of the semiconductor structure taken along the Y1-Y1 axis of FIG. 21A at the twenty-eighth-intermediate fabrication stage, according to an illustrative embodiment.

FIG. 28C is a cross-sectional view of the semiconductor structure taken along the Y2-Y2 axis of FIG. 21A at the twenty-eighth-intermediate fabrication stage, according to an illustrative embodiment.

FIG. 29A is a cross-sectional view of the semiconductor structure taken along the X-X axis of FIG. 21A at a first-intermediate fabrication stage starting from FIGS. 19A-19C, according to an alternative illustrative embodiment.

FIG. 29B is a cross-sectional view of the semiconductor structure taken along the Y1-Y1 axis of FIG. 21A at the first-intermediate fabrication stage, according to an alternative illustrative embodiment.

FIG. 29C is a cross-sectional view of the semiconductor structure taken along the Y2-Y2 axis of FIG. 21A at the first-intermediate fabrication stage, according to an alternative illustrative embodiment.

FIG. 30A is a cross-sectional view of the semiconductor structure taken along the X-X axis of FIG. 21A at a second-intermediate fabrication stage, according to an alternative illustrative embodiment.

FIG. 30B is a cross-sectional view of the semiconductor structure taken along the Y1-Y1 axis of FIG. 21A at the second-intermediate fabrication stage, according to an alternative illustrative embodiment.

FIG. 30C is a cross-sectional view of the semiconductor structure taken along the Y2-Y2 axis of FIG. 21A at the second-intermediate fabrication stage, according to an alternative illustrative embodiment.

FIG. 31A is a cross-sectional view of the semiconductor structure taken along the X-X axis of FIG. 21A at a third-intermediate fabrication stage, according to an alternative illustrative embodiment.

FIG. 31B is a cross-sectional view of the semiconductor structure taken along the Y1-Y1 axis of FIG. 21A at the third-intermediate fabrication stage, according to an alternative illustrative embodiment.

FIG. 31C is a cross-sectional view of the semiconductor structure taken along the Y2-Y2 axis of FIG. 21A at the third-intermediate fabrication stage, according to an alternative illustrative embodiment.

FIG. 32A is a cross-sectional view of the semiconductor structure taken along the X-X axis of FIG. 21A at a fourth-intermediate fabrication stage, according to an alternative illustrative embodiment.

FIG. 32B is a cross-sectional view of the semiconductor structure taken along the Y1-Y1 axis of FIG. 21A at the fourth-intermediate fabrication stage, according to an alternative illustrative embodiment.

FIG. 32C is a cross-sectional view of the semiconductor structure taken along the Y2-Y2 axis of FIG. 21A at the fourth-intermediate fabrication stage, according to an alternative illustrative embodiment.

FIG. 33A is a cross-sectional view of the semiconductor structure taken along the X-X axis of FIG. 21A at a fifth-intermediate fabrication stage, according to an alternative illustrative embodiment.

FIG. 33B is a cross-sectional view of the semiconductor structure taken along the Y1-Y1 axis of FIG. 21A at the fifth-intermediate fabrication stage, according to an alternative illustrative embodiment.

FIG. 33C is a cross-sectional view of the semiconductor structure taken along the Y2-Y2 axis of FIG. 21A at the fifth-intermediate fabrication stage, according to an illustrative embodiment.

### DETAILED DESCRIPTION

Illustrative embodiments of the invention may be described herein in the context of illustrative methods for forming nanosheet dual dielectric layer isolation that isolates one or more of a source/drain region and a gate structure from a backside power rail for a backside power delivery network (BSPDN), along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Present semiconductor processing for backside power display network schemes requires complete substrate removal, such as by shift frontside via backside power processing or direct backside contact processing. However, complete removal of the substrate may damage the replacement gate and backside power rail via even with a bottom isolation layer being present. The non-limiting illustrative embodiments disclosed herein provide methods and structures for overcoming the foregoing drawback by forming a dielectric stack containing at least a first dielectric layer and a second dielectric layer that isolates one or more of a source/drain region and a gate from a backside power rail for a backside power delivery network (BSPDN). The BSPND brings a backside power rail from the back-end-of-line to the backside of the semiconductor structure to release the congestion of the backside power rail at the frontside back-end-of-line and therefore allows for improved routing capability for both backside and frontside.

In the discussion that follows, the semiconductor structure, which will incorporate one or more integrated circuit devices, will be referred to as the “semiconductor structure 100” throughout the various intermediate stages of fabrication, as represented in all the accompanying drawings.

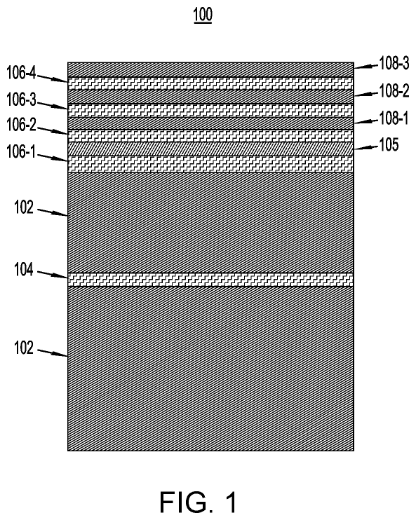

Referring now to the drawings in which like numerals represent the same of similar elements, FIGS. 1-33C illustrate various processes for fabricating semiconductor structures having a dielectric stack. Note that the same reference numeral (100) is used to denote the semiconductor structure through the various intermediate fabrication stages illustrated in FIGS. 1-33C. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-33C are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 is a cross-sectional view of a semiconductor structure 100 at a first-intermediate fabrication stage. Semiconductor structure 100 includes substrate 102. Substrate 102 may be formed of any suitable semiconductor material, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

An etch stop layer 104 is formed in the substrate 102. The etch stop layer 104 may comprise a buried oxide (BOX) layer or silicon germanium (SiGe), or another suitable material such as a III-V semiconductor epitaxial layer.

Nanosheets are initially formed over the substrate 102, where the nanosheets include sacrificial layer 105, sacrificial layers 106-1, 106-2, 106-3 and 106-4 (collectively, sacrificial layers 106), and nanosheet channel layers 108-1, 108-2 and 108-3 (collectively, nanosheet channel layers 108). The sacrificial layers 105 and 106 are illustratively formed of different sacrificial materials, such that they may be etched or otherwise removed selective to one another. In some embodiments, the sacrificial layers are formed of SiGe, but with different percentages of Ge. For example, certain ones of the sacrificial layers may have a relatively higher percentage of Ge (e.g., 55% Ge or 60% Ge), and other ones of the sacrificial layers may have a relatively lower percentage of Ge (e.g., 25% Ge or 30% Ge). Other combinations of different sacrificial materials may be used in other embodiments. The sacrificial layer 105 may have a thickness in the range of about 5 to about 20 nanometers (nm). The sacrificial layers 106 may each have a thickness of about 5 to about 20 nm.

The nanosheet channel layers 108 may be formed of Si or another suitable material (e.g., a material similar to that used for the substrate 102). The nanosheet channel layers 108 may each have a thickness of about 5 to about 20 nm.

Although four layers of the sacrificial layers 106 and three layers of the nanosheet channel layers 108 are shown, the number of sacrificial layers 106 and the nanosheet channel layers 108 should not be considered limiting and any number are contemplated.

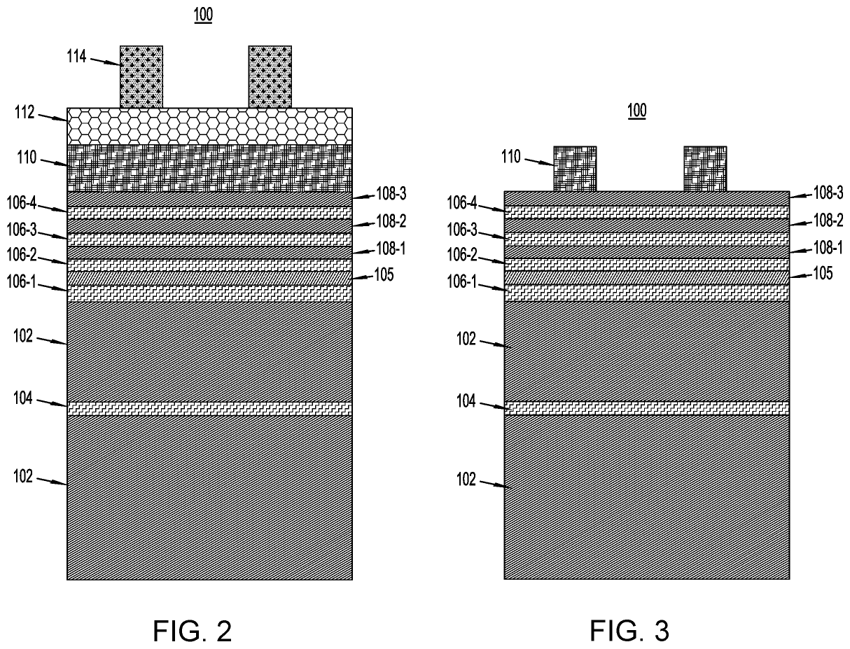

FIG. 2 illustrates semiconductor structure 100 at a second-intermediate fabrication stage. During this stage, a patterning step is carried out in which hardmask (HM) layer 110 is formed on topmost nanosheet channel layer 108-3 using any conventional deposition technique such as by physical vapor deposition (PVD), atomic layer deposition (ALD), chemical vapor deposition (CVD), etc., followed by a planarization step such as a chemical mechanical planarization (CMP) process. The HM layer 110 can be formed of any suitable material such as, e.g., amorphous silicon, or another suitable material.

A mask layer 112 (such as an organic planarization layer (OPL) or a spin-on-carbon (SOC)) is formed on HM layer 110 using any conventional deposition process such spin-on coating or any other suitable deposition process.

Photoresist 114 is formed on mask layer 112 and patterned for subsequent processing.

FIG. 3 illustrates semiconductor structure 100 at a third-intermediate fabrication stage. During this stage, semiconductor structure 100 is subjected to a suitable etching process to remove the exposed portions of HM layer 110 and mask layer 112 and exposing the topmost nanosheet channel layer 108-3. A suable etching process includes, for example, reactive ion etching (RIE) processing. The photoresist 114 and remaining mask layer 112 can be removed using any suitable technique.

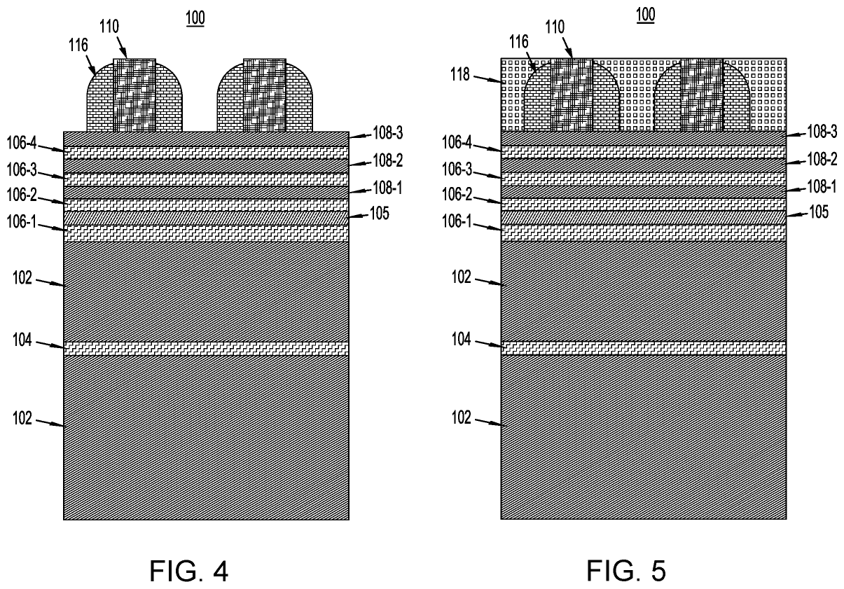

FIG. 4 illustrates semiconductor structure 100 at a fourth-intermediate fabrication stage. During this stage, sidewall spacers 116 are formed on HM layer 110 by deposing a suitable spacer material on semiconductor structure 100 using any conventional deposition technique such as by ALD, PVD, CVD, etc., followed by an etch back process. The sidewall spacers 116 may be formed of any suitable insulator, such as SiN, silicon boron carbide nitride (SiBCN), silicon oxycarbonitride (SiOCN), etc.

FIG. 5 illustrates semiconductor structure 100 at a fifth-intermediate fabrication stage. During this stage, a dielectric fill 118 is then deposited on semiconductor structure 100, followed by a planarization step such as CMP process. The dielectric fill 118 may be formed of a suitable dielectric material such as silicon dioxide (SiO₂), silicon oxycarbide (SiOC), silicon oxynitride (SiON), etc.

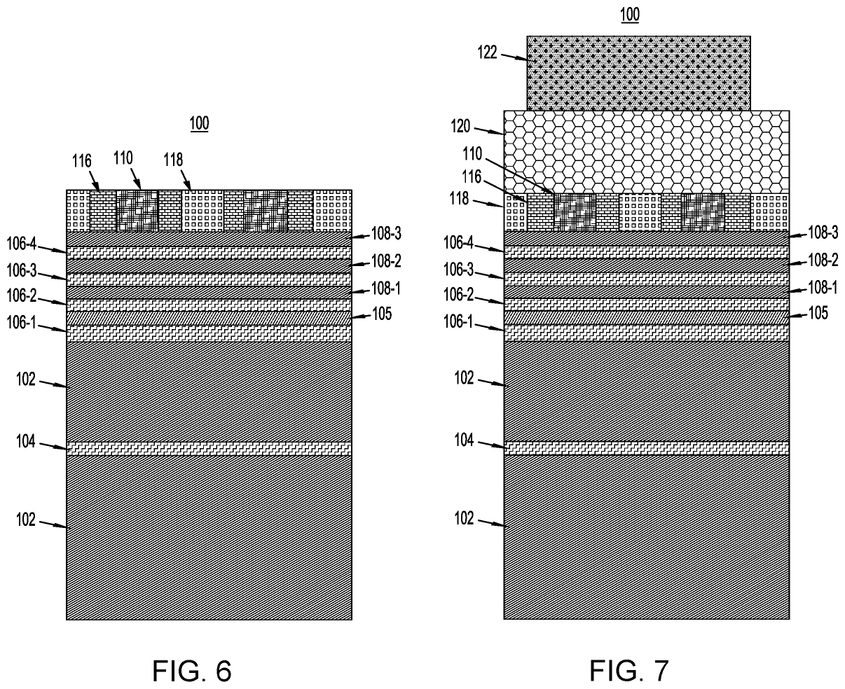

FIG. 6 illustrates semiconductor structure 100 at a sixth-intermediate fabrication stage. During this stage, another planarization step is carried out such as CMP to the top surfaces of dielectric fill 118, sidewall spacers 116 and HM layer 110.

FIG. 7 illustrates semiconductor structure 100 at a seventh-intermediate fabrication stage. During this stage, a patterning step is carried out in which a mask layer 120 (such as an OPL or a spin-on-carbon (SOC)) is formed on the top surfaces of dielectric fill 118, sidewall spacers 116 and HM layer 110 using any conventional deposition process such spin-on coating or any other suitable deposition process. Next, a photoresist 122 is formed on mask layer 120 and patterned for subsequent processing.

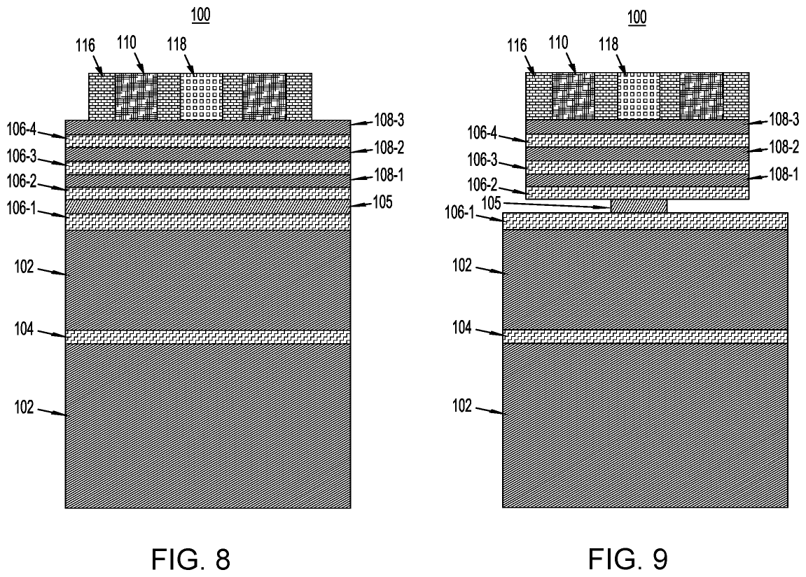

FIG. 8 illustrates semiconductor structure 100 at an eighth-intermediate fabrication stage. During this stage, semiconductor structure 100 is subjected to a suitable etching process to remove the exposed portions of mask layer 120 and dielectric fill 118 underneath mask layer 120 and exposing the topmost nanosheet channel layer 108-3. A suitable etching process includes, for example, RIE processing. The photoresist 122 and remaining mask layer 120 can be removed using any suitable technique.

FIG. 9 illustrates semiconductor structure 100 at a ninth-intermediate fabrication stage. During this stage, semiconductor structure 100 is subjected to a patterning and lithographic processing such as RIE to remove the exposed portions of nanosheet channel layers 108 and sacrificial layers 106-2, 106-3 and 106-4. Next, indentation of the sacrificial layer 105 is carried out to form an indented opening using a suitable selective etching process that is selective to sacrificial layer 105 relative to sacrificial layers 106-1 and 106-2 such as a wet or dry etch. For example, in non-limiting illustrative embodiments, a selective etching process may comprise etching in vapor phase HCl. As used herein, the term “selective” in reference to a material removal process denotes that the rate of material removal for a first material is greater than the rate of removal for at least another material of the structure to which the material removal process is being applied.

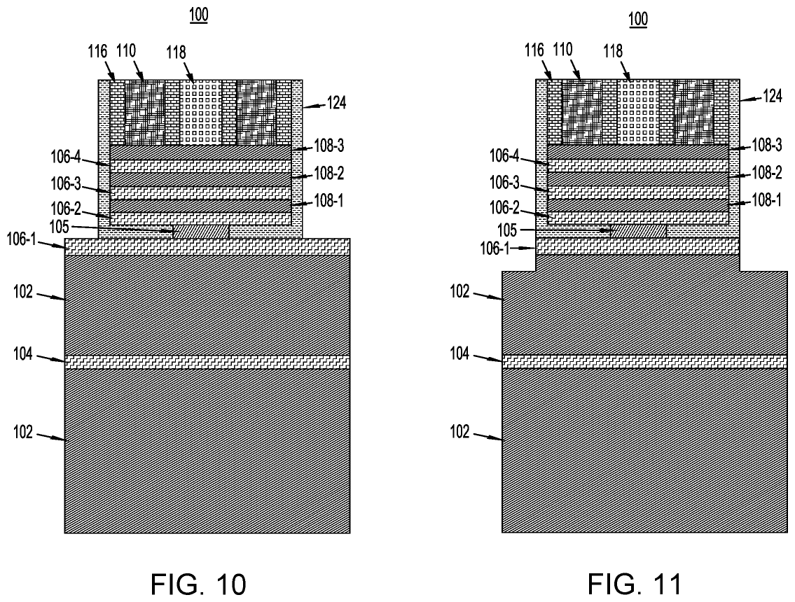

FIG. 10 illustrates semiconductor structure 100 at a tenth-intermediate fabrication stage. During this stage, dielectric layer 124 is formed in the indented opening of sacrificial layer 105 and on sidewalls of sacrificial layers 106-2, 106-3 and 106-4, nanosheet channel layers 108 and sidewall spacers 116. The dielectric layer 124 can be formed by conformal dielectric deposition and anisotropic dielectric etching. A suitable material for dielectric layer 124 may be SiN.

FIG. 11 illustrates semiconductor structure 100 at an eleventh-intermediate fabrication stage. During this stage, exposed portions of sacrificial layer 106-1 and a portion of substrate 102 underneath sacrificial layer 106-1 are removed using a suitable etching process such as RIE.

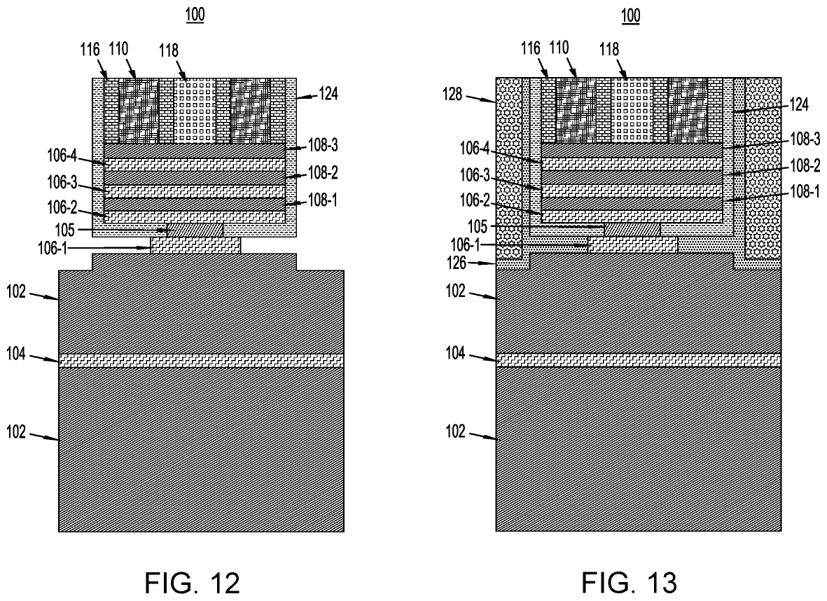

FIG. 12 illustrates semiconductor structure 100 at a twelfth-intermediate fabrication stage. During this stage, a portion of sacrificial layer 106-1 is selectively removed using a suitable wet or dry etch.

FIG. 13 illustrates semiconductor structure 100 at a thirteenth-intermediate fabrication stage. During this stage, dielectric layer 126 is formed on the exposed surfaces of substrate 102, on sidewalls of dielectric layer 124 and on the sidewalls of the remaining portion of sacrificial layer 106-1. The dielectric layer 126 can be formed by conformal dielectric deposition and anisotropic dielectric etching. A suitable material for dielectric layer 126 may be SiC, SiOC, etc. In one embodiment, dielectric layer 126 is formed from a material different than dielectric layer 124. As shown below in the non-limiting illustrative embodiments, dielectric layer 124 and dielectric layer 126 form a dielectric stack on the illustrative semiconductor structure 100.

Next, shallow trench isolation (STI) regions 128 can be formed on substrate 102 and dielectric layer 126 using conventional deposition techniques such as ALD, PVD, CVD, etc. STI regions 128 includes a dielectric material such as silicon oxide or silicon oxynitride, and is formed by methods known in the art. For example, in one illustrative embodiment, STI regions 128 are a shallow trench isolation oxide layer. Following formation of STI regions 128, a planarization process such as CMP can be carried out.

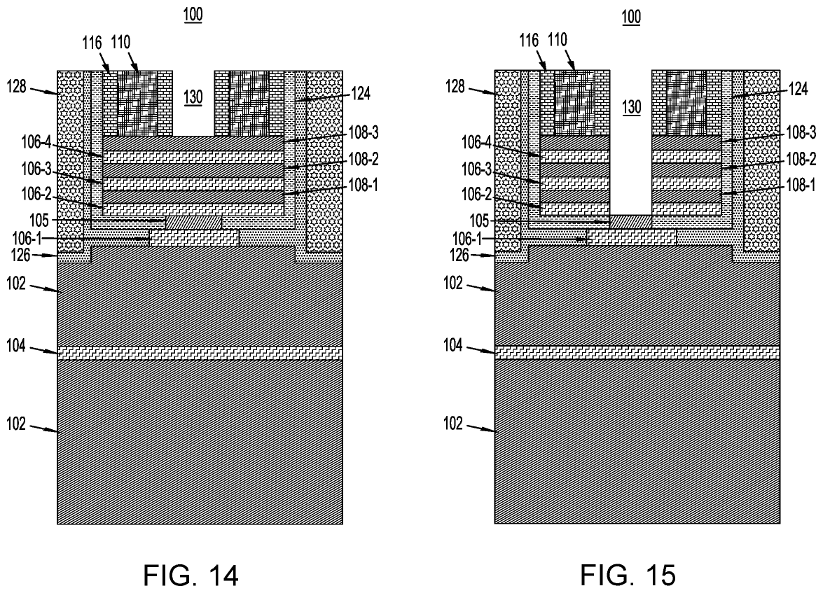

FIG. 14 illustrates semiconductor structure 100 at a fourteenth-intermediate fabrication stage. During this stage, dielectric fill 118 is selectively removed to form opening 130. Dielectric fill 118 can be selectively removed using any suitable wet or dry etch.

FIG. 15 illustrates semiconductor structure 100 at a fifteenth-intermediate fabrication stage. During this stage, a selective etch process is carried in opening 130 to expose a top surface of sacrificial layer 105. A selective etch process can be, for example, RIE, to selectively remove nanosheet channel layers 108-1, 108-2 and 108-3 and sacrificial layers 106-2, 106-3 and 106-4 in opening 130.

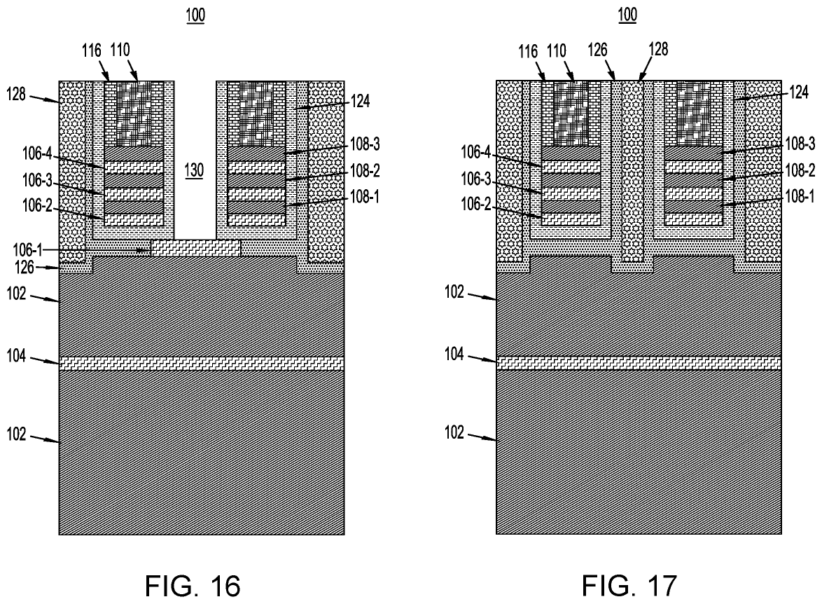

FIG. 16 illustrates semiconductor structure 100 at a sixteenth-intermediate fabrication stage. During this stage, a selective etch process is carried in opening 130 to remove sacrificial layer 105. A selective etch process can be, for example, a suitable dry or wet etch. Next, dielectric layer 124 is deposited in opening 130 using any conventional deposition technique such as ALD, PVD, CVD, etc., followed by an etch back process, for example, RIE, so that it remains on the sidewalls of opening 130.

FIG. 17 illustrates semiconductor structure 100 at a seventeenth-intermediate fabrication stage. During this stage, a selective etch process is carried in opening 130 to remove sacrificial layer 106-1 and a portion of substrate 102 using, for example, RIE. Next, dielectric layer 126 is deposited on the exposed portion of substrate 102 and on sidewalls of dielectric layer 124 in opening 130 using any conventional deposition technique such as ALD, PVD, CVD, etc. STI regions 128 are then formed in opening 130, followed by a planarization process such as CMP.

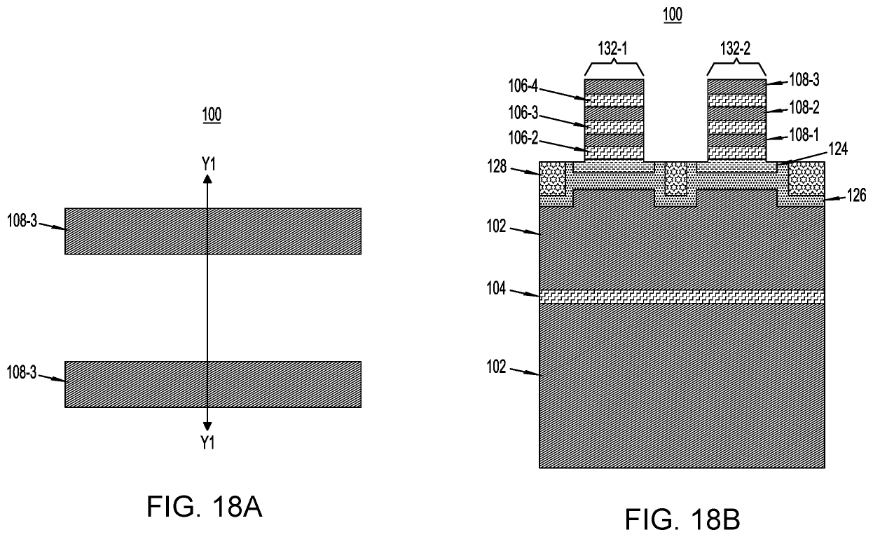

FIGS. 18A and 18B illustrate semiconductor structure 100 at an eighteenth-intermediate fabrication stage. During this stage, a portion of STI regions 128, and dielectric layers 124 and 126 are removed using, for example, an anisotropic etch such as RIE, to reveal FET stacks 132-1 and 132-2 containing sacrificial layers 106-2, 106-3 and 106-4 and nanosheet channel layers 108-1, 108-2 and 108-3. Each of the FET stacks 132-1 and 132-2 can contain a FET device. The FET devices may comprise an nFET device or a pFET device and other FET devices may comprise an nFET device or a pFET device. In addition, although two FET stacks 132-1 and 132-2 are shown, the number of sets of FET stacks should not be considered limiting and any number are contemplated. Once FET stacks 132-1 and 132-2 are revealed, the remaining HM layer 110 is removed by, for example, an ash etching process.

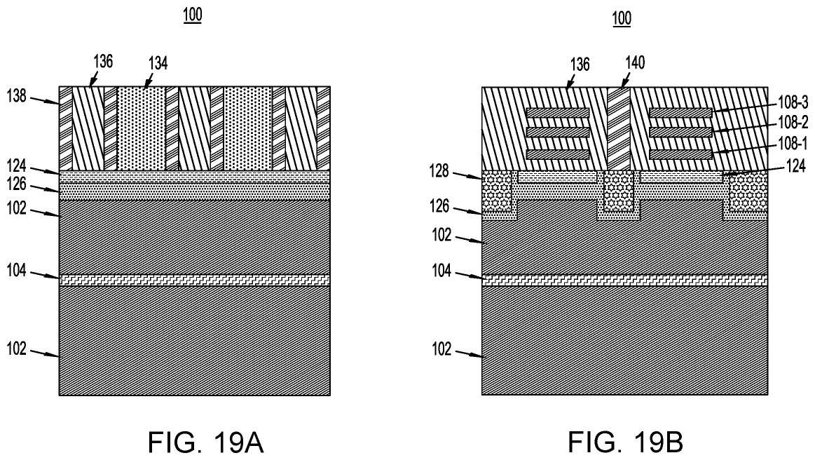

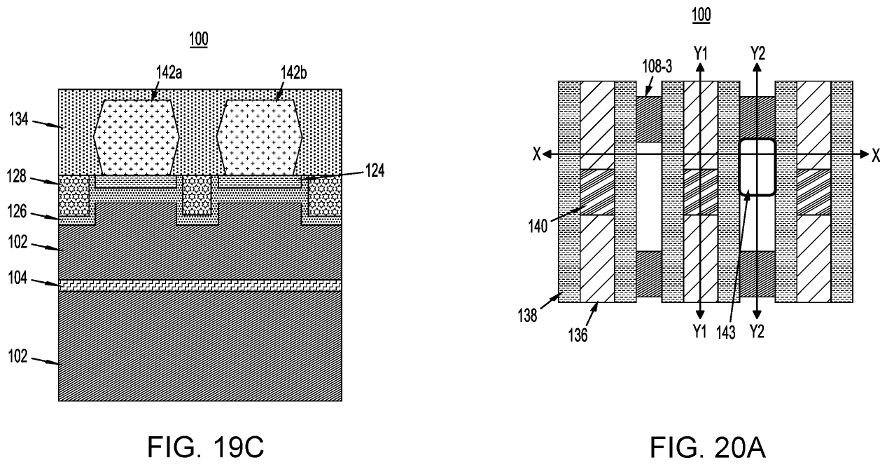

FIGS. 19A-19C illustrate semiconductor structure 100 at a nineteenth-intermediate fabrication stage. During this stage, processing of the structure includes forming an interlayer dielectric (ILD) layer 134, a gate stack layer 136, sidewall spacers 138, dielectric pillar 140 and source/drain regions 142a and 142b. To form the structure shown in FIGS. 19A-19C, dummy gates are first formed over the nanosheets (not shown), followed by formation of sidewall spacers 138 by conformal dielectric liner deposition and anisotropic dielectric liner etching. Next, the source/drain regions 142a and 142b and ILD layer 134 are formed, followed by poly open CMP, dielectric pillar 140 formation, and removal of the dummy gates and sacrificial layers 106-2, 106-3 and 106-4. Following removal of the dummy gates, the gate stack layer 136 is formed (e.g., using replacement high-k metal gate (HKMG) processing). For example, one or more wet or dry etching processes can be performed to remove the dummy gates and sacrificial layers 106-2, 106-3 and 106-4 to thereby define a gate cavity where a replacement gate structure will subsequently be formed for the semiconductor structure 100. Gate stack layer 136 is then formed in the gate cavity as a replacement gate structure. The gate stack layer 136 depicted herein is intended to be representative in nature of any type of gate structure that may be employed in manufacturing integrated circuit products using so-called gate-last (replacement gate) manufacturing techniques.

The ILD layer 134 is formed on the source/drain regions 142a and 142b and over the top of the STI regions 128 by conventional deposition processes such as PVD, ALD, CVD and/or plating. The ILD layer 134 may be formed of any suitable isolating material, such as SiO₂, SiOC, SiON, etc.

The gate stack layer 136 may comprise a gate dielectric layer and a gate conductor layer. The gate dielectric layer may be formed of a high-k dielectric material. Examples of high-k dielectric materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate stack layer 136 may have a uniform thickness in the range of about 1 nm to about 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The sidewall spacers 138 may be formed of any suitable insulator, such as SiN, silicon boron carbide nitride (SiBCN), silicon oxycarbonitride (SiOCN), etc.

Dielectric pillar 140 can be formed by first performing a gate cut in gate stack layer 136 by conventional techniques to form an opening (not shown) which stops on the STI regions 128. Next, a dielectric fill is deposited in the opening and fills the opening to form dielectric pillar 140. The dielectric pillar 140 may be formed by filling a dielectric material such as, for example, SiN, SiO₂, SiOC, SiOCN, SiBCN, SiC, etc. in the opening, followed by planarization using CMP or other suitable planarization process. In illustrative embodiments, FIG. 19B shows dielectric pillar 140 formed in gate stack layer 136 to form a FET cell having, for example, an NFET region and a PFET region, or an NFET region and an NFET region, or a PFET region and a PFET region.

The source/drain regions 142a and 142b may be formed using epitaxial growth processes. The source/drain regions 142a and 142b may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). In some embodiments, the epitaxy process includes in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

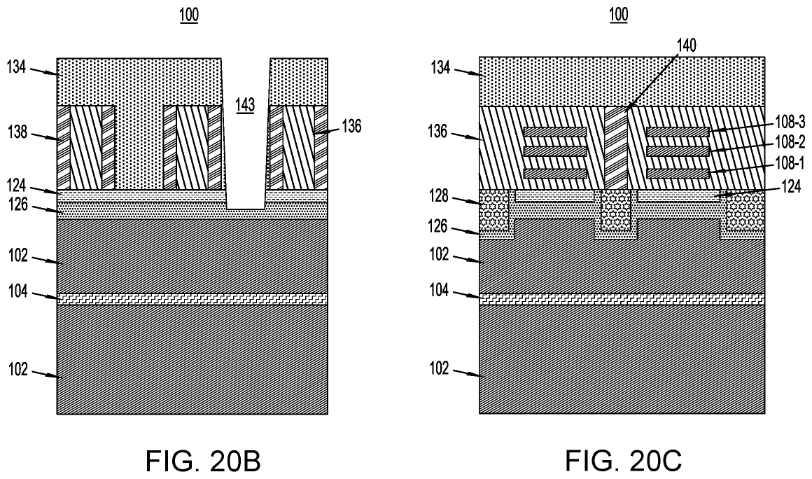

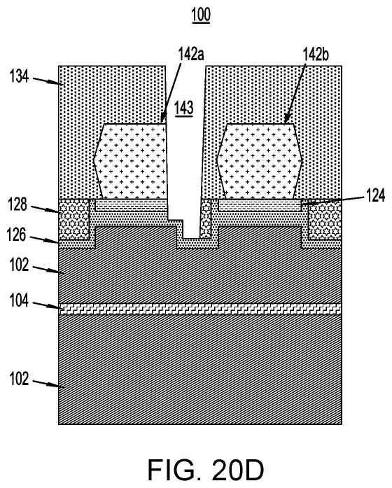

FIGS. 20A-28C illustrate a shift frontside via backside power processing scheme of semiconductor structure 100. FIGS. 20A-20D illustrate semiconductor structure 100 at a twentieth-intermediate fabrication stage. During this stage, via-to-backside power rail openings 143 are formed by depositing an additional amount of ILD layer 134 and utilizing conventional lithographic and selective etch processes such as a wet or dry etch etching process in ILD layer 134. FIG. 20D illustrates an etch back of a portion of a sidewall of source/drain region 142a and dielectrics layer 124 and 126 such that the lower portion of the via-to-backside power rail openings 143 includes a step-wise configuration.

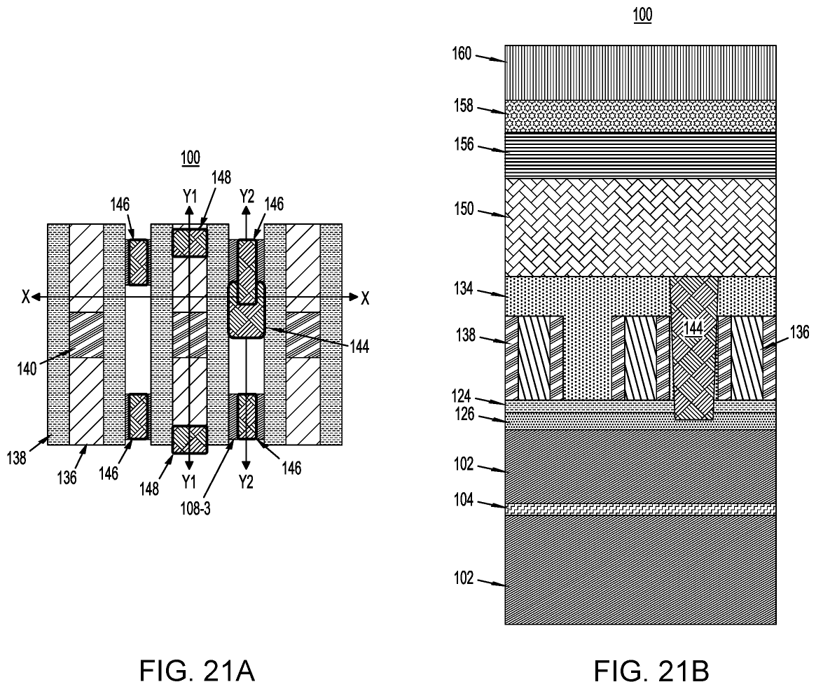

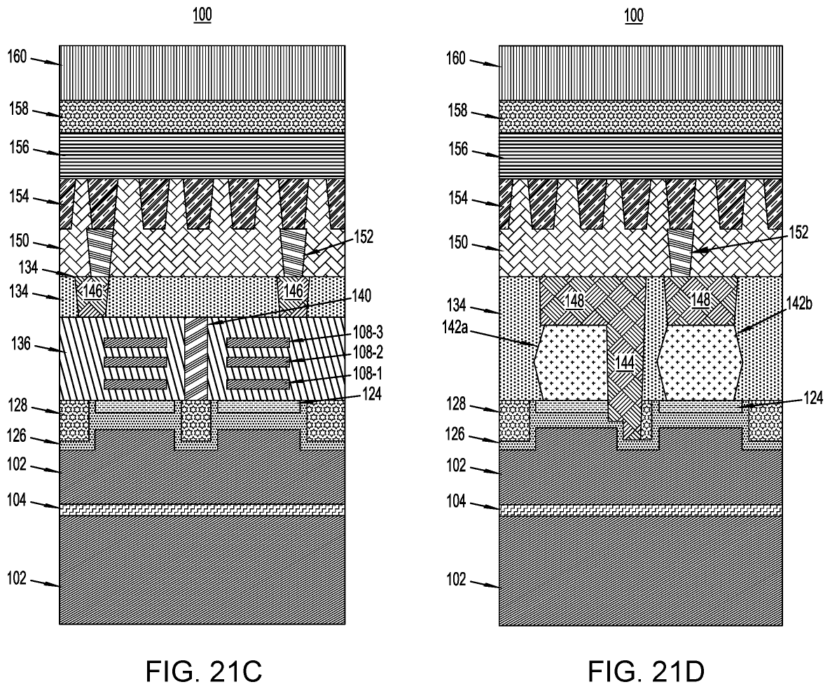

FIGS. 21A-21D illustrate semiconductor structure 100 at a twenty-first-intermediate fabrication stage. During this stage, via-to-backside power rails 144 are formed by deposition of a conductive metal in via-to-backside power rail openings 143. The conductive metal is deposited by conventional deposition processes such as PVD, ALD, CVD, and/or plating. The conductive metal can be any suitable conductive material such as, for example, platinum (Pt), cobalt (Co), ruthenium (Ru), iridium (Ir), molybdenum (Mo), or any other suitable conductive material.

FIG. 21D illustrates the via-to-backside power rails 144 having a lower portion comprising a step-wise configuration and an upper portion located on a sidewall of the source/drain regions 142a.

Middle-of-the-line gate contacts 146 and source/drain contacts 148 are formed in ILD layer 134 by patterning and etching vias in the ILD layer 134. A suitable conductive metal is then deposited in the vias to form middle-of-the-line gate contacts 146 and source/drain contacts 148 and can be any conductive metal as discussed above.

ILD layer 150 is formed on semiconductor structure 100 and has a first via level V₀ containing metal vias 152 and a first metallization level M₁ containing metal containing lines 154. ILD layer 150 can be formed of a similar material and by a similar process as ILD layer 134. First via level V₀ and first metallization level M₁ can be formed by patterning and etching vias in the ILD layer 150. A suitable conductive metal is then deposited in the vias to form metal vias 152 and metal containing lines 154 and can be any conductive metal as discussed above.

Semiconductor structure 100 further includes frontside back-end-of-line (BEOL) interconnect 156 that is bonded to a carrier wafer 160 via a bonding layer 158. The frontside BEOL interconnect 156 includes various BEOL interconnect structures. For example, frontside BEOL interconnect 156 is a metallization structure that includes one or more metal layers disposed on a side of semiconductor structure 100 opposite of the side on which the backside BEOL metallization structure is disposed. The metal layers of the frontside BEOL interconnect 156 each have metal lines for making interconnections to the semiconductor device.

The carrier wafer 160 may be formed of materials similar to that of the substrate 102, and may be formed over the frontside BEOL interconnect 156 with the bonding layer 158 using a wafer bonding process, such as dielectric-to-dielectric bonding. Bonding layer 158 can be an oxide material capable of bonding the carrier wafer 160 to frontside BEOL interconnect 156.

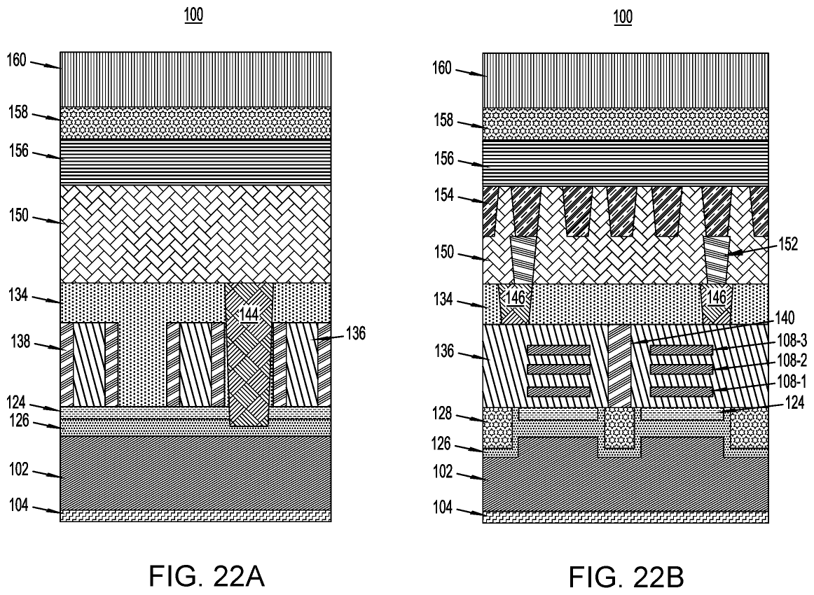

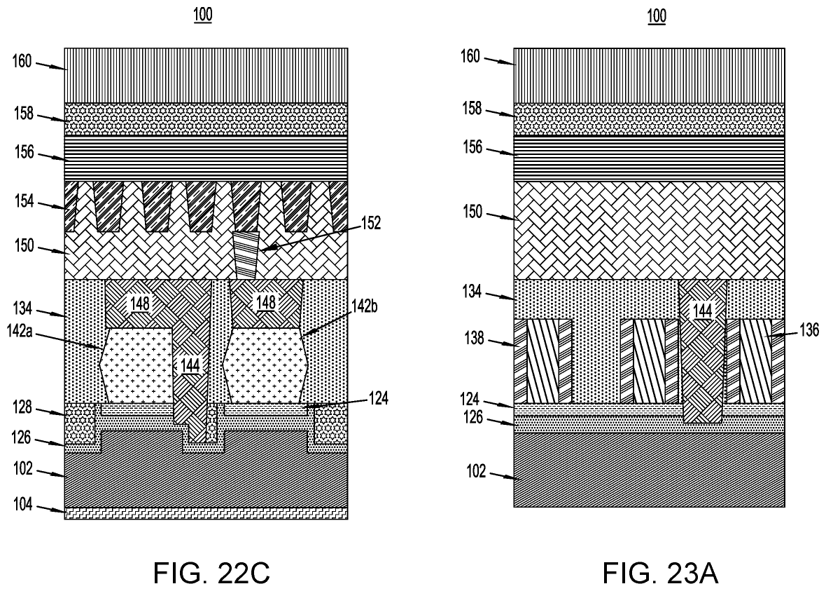

FIGS. 22A-22C illustrate semiconductor structure 100 at a twenty-second-intermediate fabrication stage. During this stage, portions of the substrate 102 may be removed from the backside using, for example, substrate grinding, CMP and a wet etch to selectively remove substrate 102 until the etch stop layer 104 is reached. This can be accomplished, for example, by flipping the semiconductor structure 100 over using the carrier wafer 160 so that the backside of the substrate 102 (i.e., the back surface) is facing up.

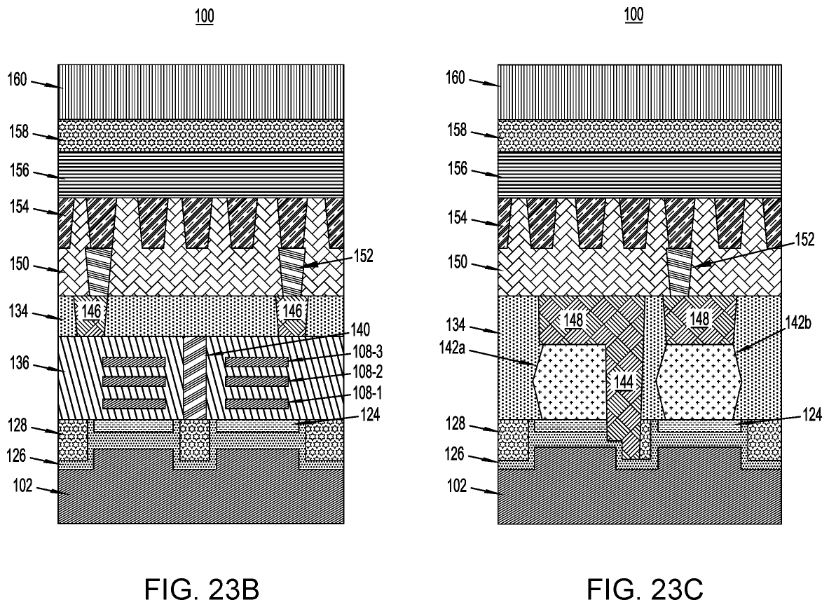

FIGS. 23A-23C illustrate semiconductor structure 100 at a twenty-third-intermediate fabrication stage. During this stage, the etch stop layer 104 is selectively removed using, for example, a wet etch to selectively remove etch stop layer 104 until substrate 102 is reached.

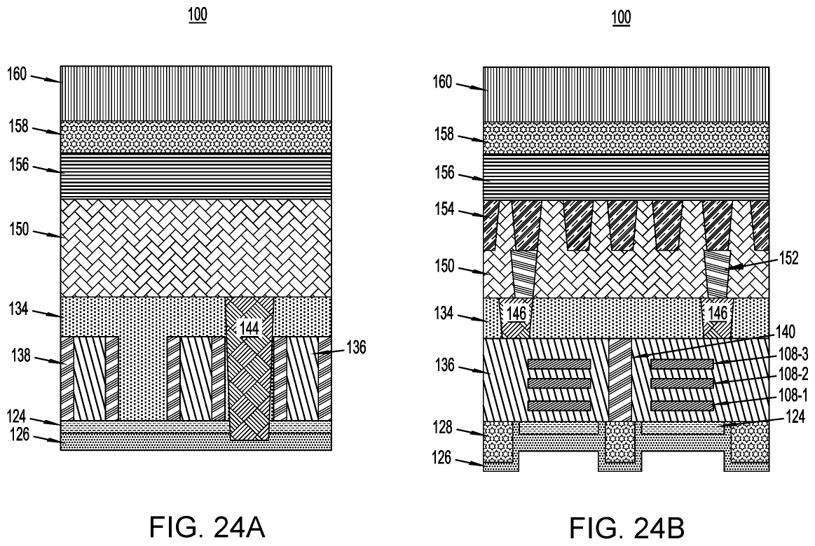

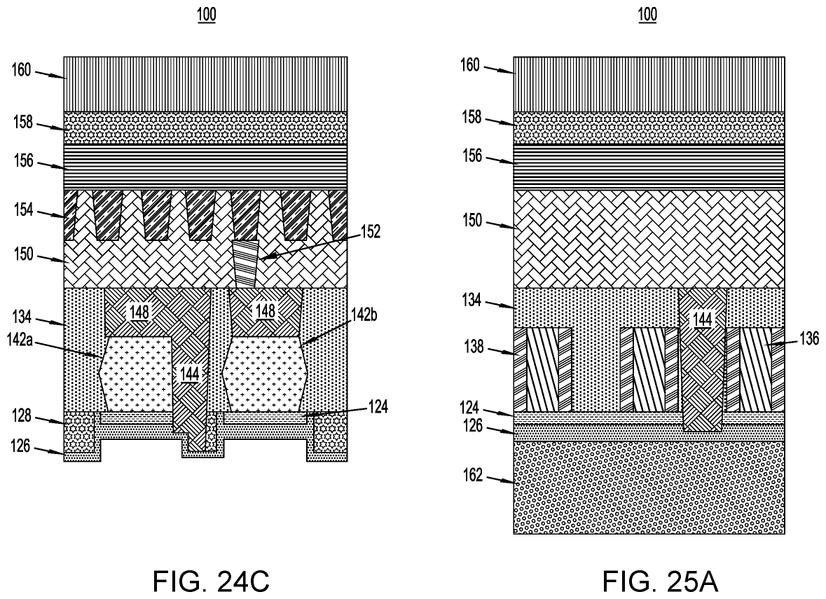

FIGS. 24A-24C illustrate semiconductor structure 100 at a twenty-fourth-intermediate fabrication stage. During this stage, the remaining portions of the substrate 102 are removed to expose dielectric layer 126. The remaining portions of the substrate 102 can be removed utilizing a selective etch process such as a wet etch.

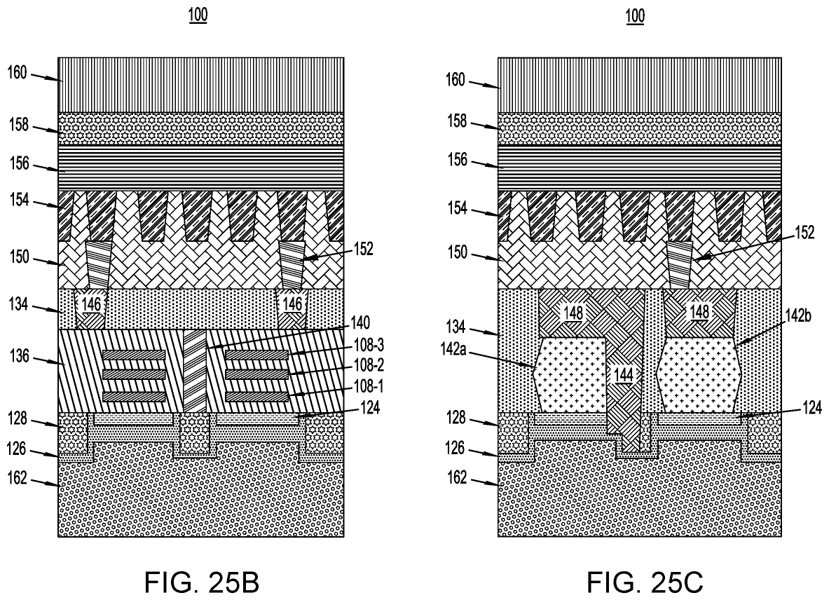

FIGS. 25A-25C illustrate semiconductor structure 100 at a twenty-fifth-intermediate fabrication stage. During this stage, backside ILD layer 162 may be formed of similar materials and similar processes as ILD layer 134. The material of the backside ILD layer 162 may initially be overfilled, followed by planarization (e.g., using CMP).

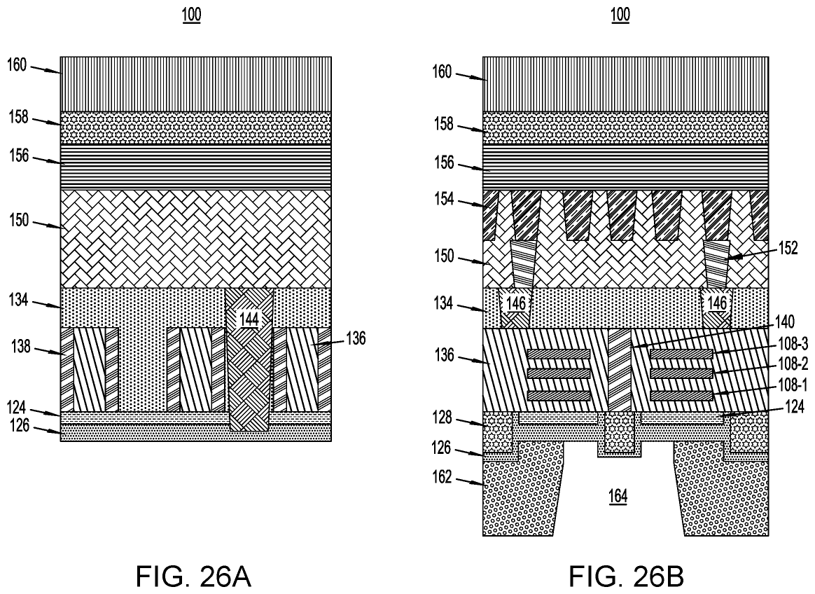

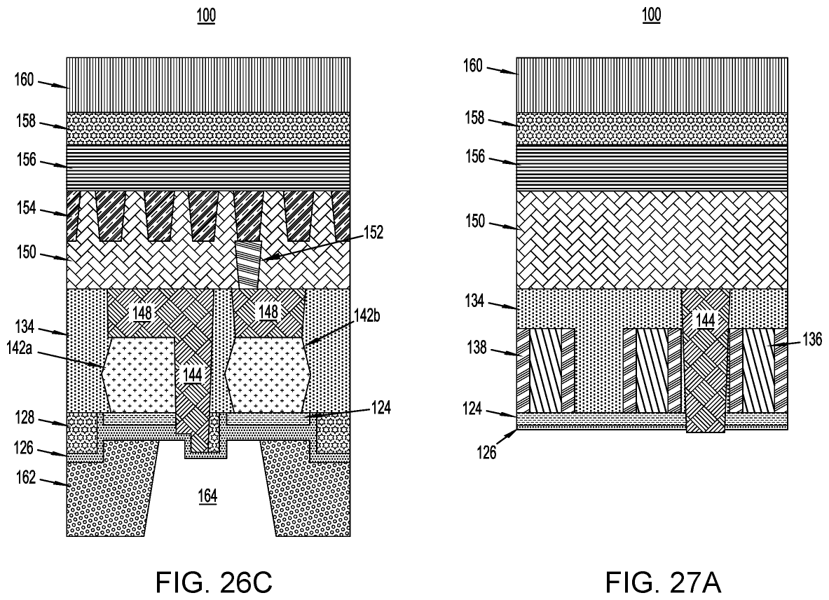

FIGS. 26A-26C illustrate semiconductor structure 100 at a twenty-sixth-intermediate fabrication stage. During this stage, backside power rail openings 164 are formed in backside ILD layer 162. Backside power rail openings 164 can be formed by first patterning and etching lines in the exposed backside ILD layer 162 to expose dielectric layer 126 using any suitable wet or dry etch.

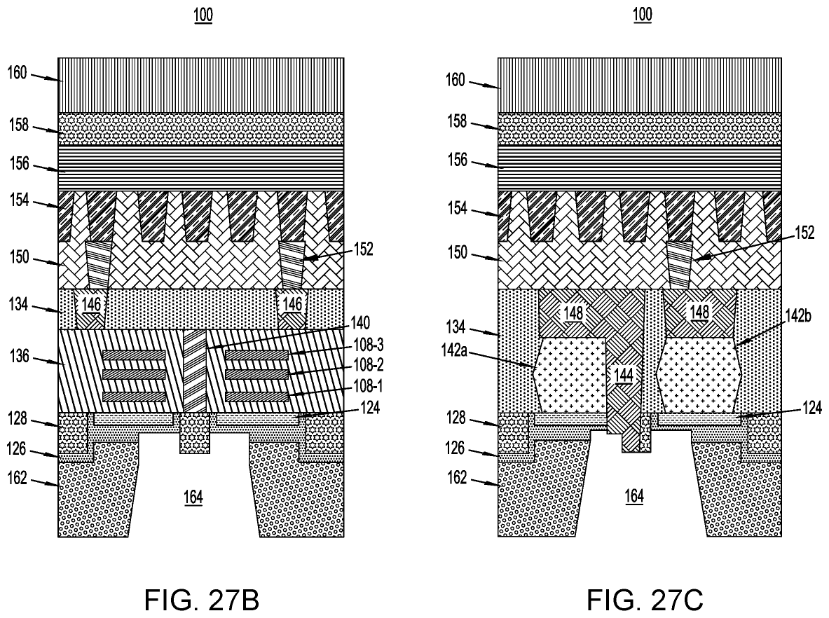

FIGS. 27A-27C illustrate semiconductor structure 100 at a twenty-seventh-intermediate fabrication stage. During this stage, the exposed dielectric layer 126 in backside power rail openings 164 is selectively removed relative to dielectric layer 124 by an isotropic etch back. FIGS. 27A and 27C show that the selective removal of dielectric layer 126 exposes a bottom surface of via-to-backside power rails 144. FIGS. 27B and 27C show that the selective removal of dielectric layer 126 exposes a bottom surface of STI regions 128.

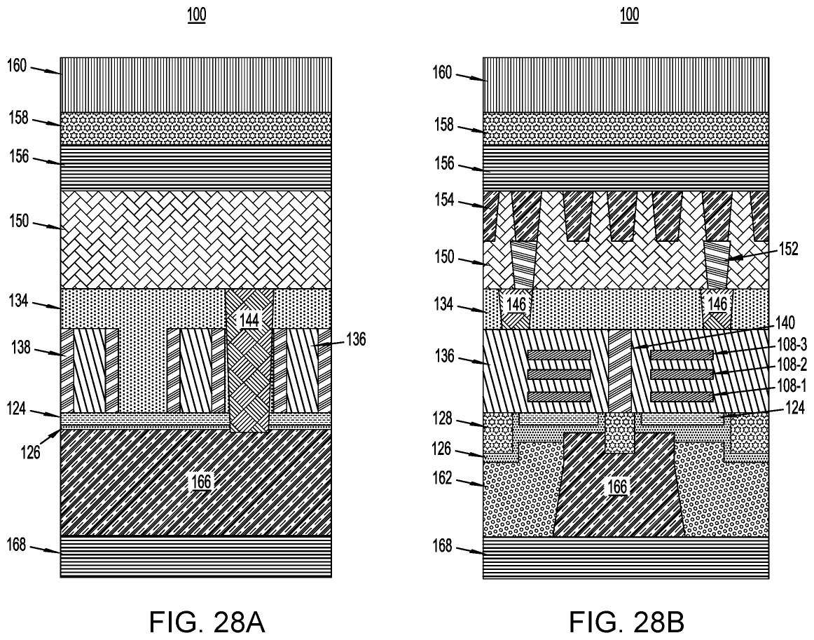

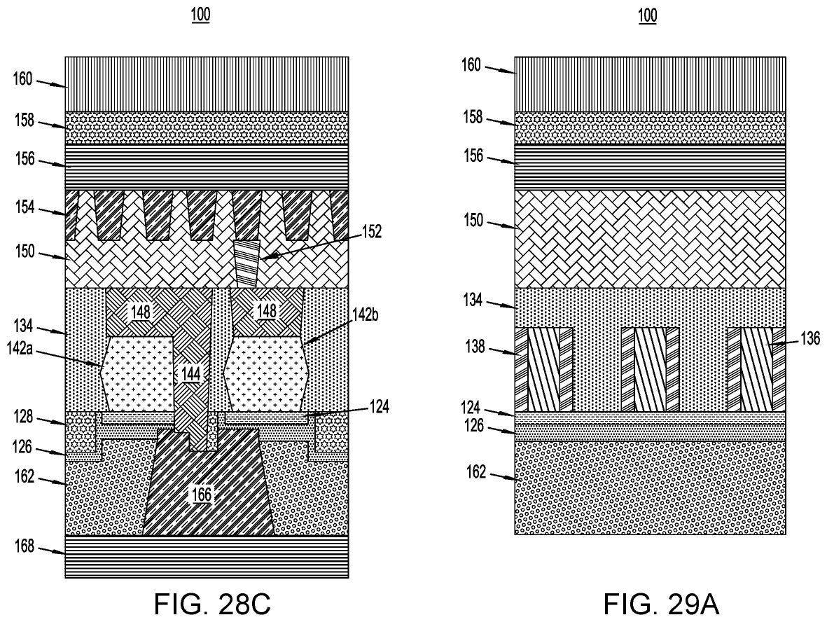

FIGS. 28A-28C illustrate semiconductor structure 100 at a twenty-eighth-intermediate fabrication stage. During this stage, a suitable conductive metal is then deposited in backside power rail openings 164, followed by CMP to remove any metal on top of backside ILD layer 162 to form backside power rails 166. A suitable conductive metal can be any of the metals discussed above.

Backside power delivery network 168 is formed over the structure including backside power rails 166 and is based on creation of a wiring scheme that is disposed on both sides of the device layer (front end of line structure).

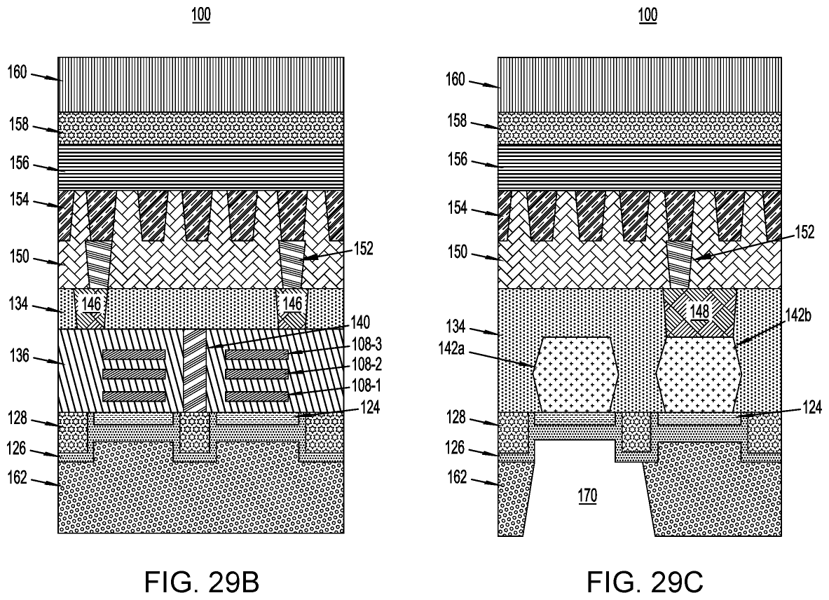

FIGS. 29A-33C are illustrative of an alternative embodiment starting from FIGS. 19A-19C utilizing direct backside contact processing. FIGS. 29A-29C illustrate semiconductor structure 100 at a first-intermediate fabrication stage where similar processing steps discussed above are utilized to arrive at the starting semiconductor structure 100 without forming via-to-backside power rails 144. FIGS. 29A-29C illustrate semiconductor structure 100 taken along the X-X axis, Y1-Y1 axis and Y2-Y2, respectively, of FIG. 21A. For example, middle-of-the-line gate contacts 146 and source/drain contact 148 are formed in ILD layer 134 by patterning and etching vias in the ILD layer 134. A suitable conductive metal is then deposited in the vias to form middle-of-the-line gate contacts 146 and source/drain contact 148 and can be any conductive metal as discussed above.

ILD layer 150 is formed on semiconductor structure 100 and has a first via level V₀ containing metal vias 152 and a first metallization level M₁ containing metal containing lines 154. ILD layer 150 can be formed of a similar material and by a similar process as ILD layer 134. First via level V₀ and first metallization level M₁ can be formed by patterning and etching vias in the ILD layer 150. A suitable conductive metal is then deposited in the vias to form metal vias 152 and metal containing lines 154 and can be any conductive metal as discussed above.

Semiconductor structure 100 further includes frontside BEOL interconnect 156 that is bonded to carrier wafer 160 via bonding layer 158. The frontside BEOL interconnect 156 includes various BEOL interconnect structures. For example, frontside BEOL interconnect 156 is a metallization structure that includes one or more metal layers disposed on a side of semiconductor structure 100 opposite of the side on which the backside BEOL metallization structure is disposed. The metal layers of the frontside BEOL interconnect 156 each have metal lines for making interconnections to the semiconductor device.

The carrier wafer 160 may be formed of materials similar to that of the substrate 102, and may be formed over the frontside BEOL interconnect 156 with the bonding layer 158 using a wafer bonding process, such as dielectric-to-dielectric bonding. Bonding layer 158 can be an oxide material capable of bonding the carrier wafer 160 to frontside BEOL interconnect 156.

Next, portions of the substrate 102 may be removed from the backside using, for example, substrate grinding, CMP and a wet etch to selectively remove substrate 102 until the etch stop layer 104 is reached. This can be accomplished, for example, by flipping the semiconductor structure 100 over using the carrier wafer 160 so that the backside of the substrate 102 (i.e., the back surface) is facing up. Etch stop layer 104 is then selectively removed using, for example, a wet etch to selectively remove etch stop layer 104 until substrate 102 is reached.

The remaining portions of the substrate 102 are removed to expose dielectric layer 126. The remaining portions of the substrate 102 can be removed utilizing a selective etch process such as a wet etch. Backside ILD layer 162 may be formed of similar materials and similar processes as ILD layer 134. The material of the backside ILD layer 162 may initially be overfilled, followed by planarization (e.g., using CMP).

Next, a backside contact opening 170 is formed in backside ILD layer 162 under source/drain region 142a of source/drain regions 142a and 142b. Backside contact opening 170 can be formed by first patterning and etching a via in the exposed backside ILD layer 162 to expose dielectric layer 126 using any suitable wet or dry etch.

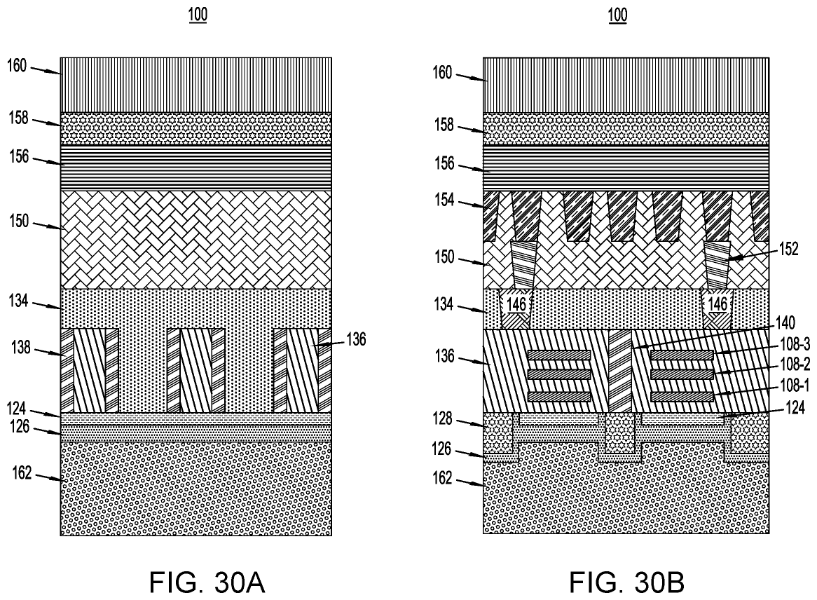

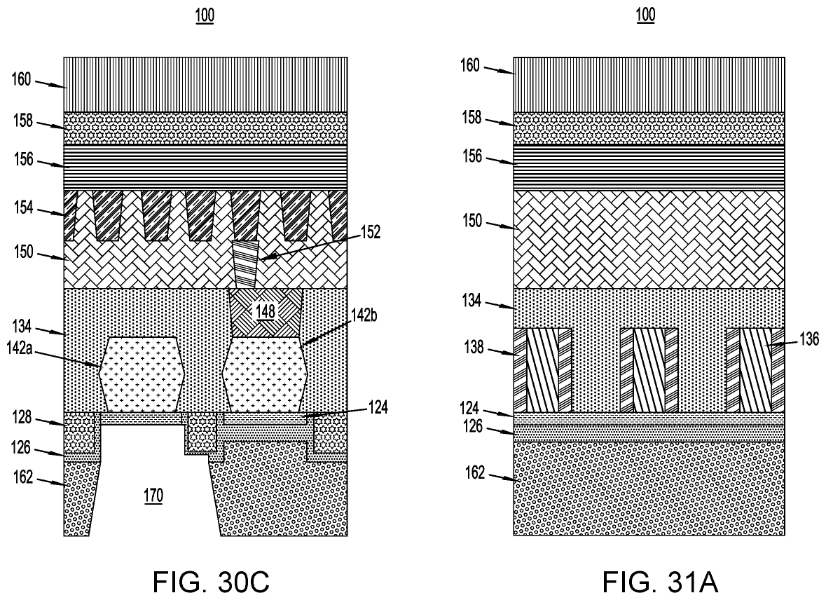

FIGS. 30A-30C illustrate semiconductor structure 100 at a second-intermediate fabrication stage. During this stage, the exposed dielectric layer 126 in backside contact opening 170 is selectively removed relative to dielectric layer 124 by an isotropic etch back. The selective removal of dielectric layer 126 exposes dielectric layer 124.

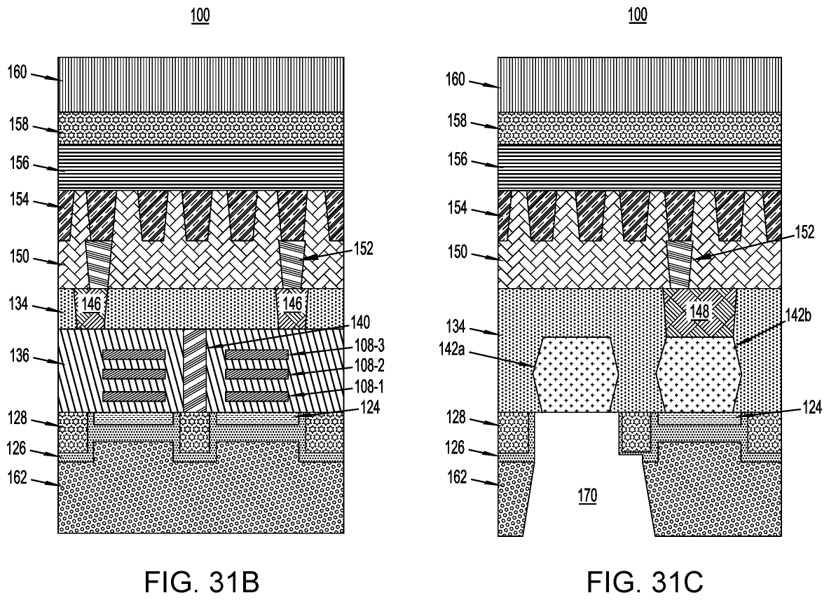

FIGS. 31A-31C illustrate semiconductor structure 100 at a third-intermediate fabrication stage. During this stage, the exposed dielectric layer 124 in backside contact opening 170 is selectively removed by an isotropic etch back. The selective removal of dielectric layer 124 exposes the source/drain region 142a.

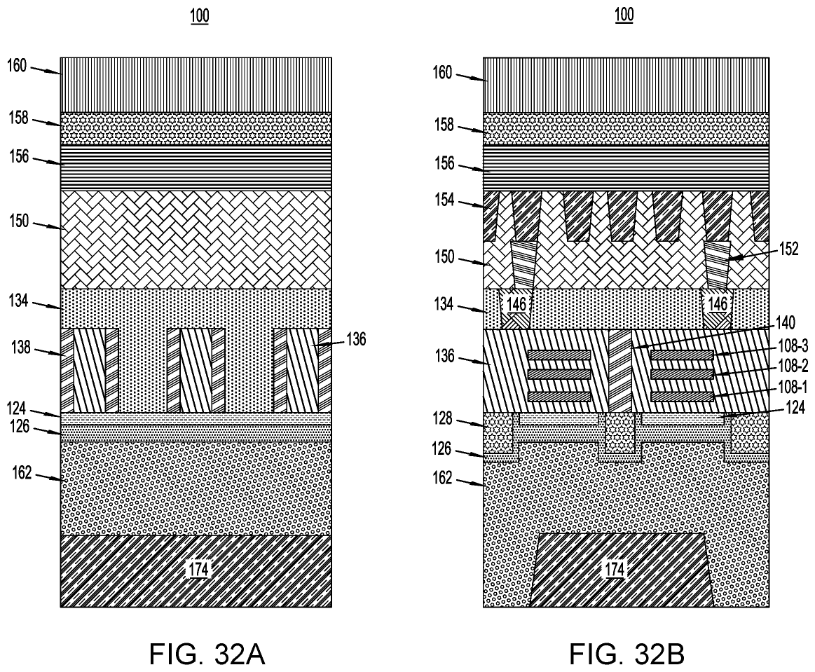

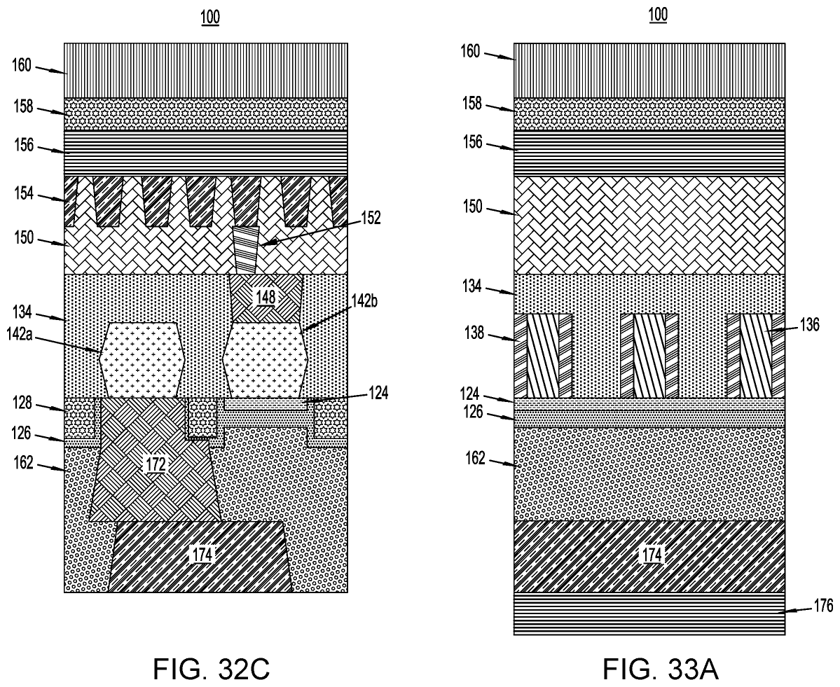

FIGS. 32A-32C illustrate semiconductor structure 100 at a fourth-intermediate fabrication stage. During this stage, a suitable conductive metal is then deposited in backside contact opening 170, followed by CMP to remove any metal on top of backside ILD layer 162 to form backside source/drain contact 172. A suitable conductive metal can be any of the metals discussed above. FIG. 32C illustrates backside source/drain contact 172 with an upper surface having a step-wise configuration comprising a top portion in contact with the source/drain regions 142a and a bottom portion extending between the source/drain regions 142a and 142b.

Next, a backside power rail 174 is formed on backside source/drain contact 172 by first depositing an additional amount of backside ILD layer 162 on semiconductor structure 100 include backside source/drain contact 172, followed by patterning and lithographic processing to form a backside power rail opening. A suitable conductive metal is then deposited in the backside contact opening 170, followed by CMP to remove any metal on top of backside ILD layer 162 to form backside power rail 174.

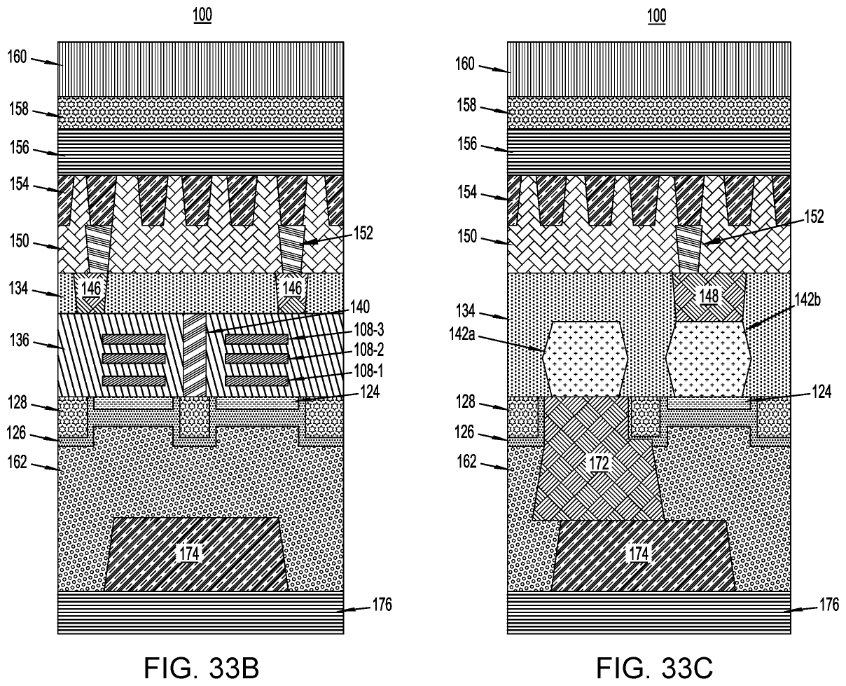

FIGS. 33A-33C illustrate semiconductor structure 100 at a fifth-intermediate fabrication stage. During this stage, backside power delivery network 176 is formed over the structure including backside power rail 174 and is based on creation of a wiring scheme that is disposed on both sides of the device layer (front end of line structure).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a frontside source/drain region; and
a dielectric stack disposed on a bottom surface of the frontside source/drain region;
wherein the dielectric stack comprises a first dielectric layer and a second dielectric layer.

2. The semiconductor structure of claim 1, further comprising a backside power rail disposed on the dielectric stack and separated from the frontside source/drain region.

3. The semiconductor structure of claim 2, further comprising a via-to-backside power rail connected to the backside power rail.

4. The semiconductor structure of claim 3, wherein the backside power rail is connected to the via-to-backside power rail from a backside of the semiconductor structure.

5. The semiconductor structure of claim 3, wherein the via-to-backside power rail comprises a lower portion located on the backside power rail and an upper portion located on a sidewall of the frontside source/drain region.

6. The semiconductor structure of claim 5, wherein the lower portion of the via-to-backside power rail comprises a step-wise configuration.

7. The semiconductor structure of claim 2, further comprising a frontside source/drain contact disposed on the frontside source/drain region, wherein the frontside source/drain contact is connected to the backside power rail by a via-to-backside power rail.

8. The semiconductor structure of claim 1, which is part of a backside power delivery network.

9. The semiconductor structure of claim 1, wherein the first dielectric layer comprises a first dielectric material and the second dielectric layer comprises a second dielectric material different from the first dielectric material.

10. A semiconductor structure, comprising:
a dielectric stack disposed on a bottom surface of at least one frontside gate; and
a backside power rail disposed on the dielectric stack and separated from the at least one frontside gate;
wherein the dielectric stack comprises a first dielectric layer and a second dielectric layer.

11. The semiconductor structure of claim 10, wherein the at least one frontside gate comprises a first frontside gate and a second frontside gate.

12. The semiconductor structure of claim 11, wherein the first frontside gate is part of a first nanosheet channel and the second frontside gate is part of a second nanosheet channel separated from the first nanosheet channel by a dielectric pillar.

13. The semiconductor structure of claim 10, further comprising a via-to-backside power rail disposed on the backside power rail.

14. The semiconductor structure of claim 10, wherein the first dielectric layer comprises a first dielectric material and the second dielectric layer comprises a second dielectric material different from the first dielectric material.

15. A semiconductor structure, comprising:
a first dielectric stack disposed on a bottom surface of a first frontside source/drain region;
a first frontside source/drain contact disposed on a top surface of the first frontside source/drain region;
a backside power rail disposed on the first dielectric stack and separated from the first frontside source/drain region; and
a via-to-backside power rail disposed on a sidewall of the first frontside source/drain region to connect the backside power rail to the first frontside source/drain contact;
wherein the first dielectric stack comprises a first dielectric layer and a second dielectric layer.

16. The semiconductor structure of claim 15, further comprising:
a second frontside source/drain region adjacent the first frontside source/drain region;
a second dielectric stack disposed on a bottom surface of the second frontside source/drain region and on a top surface of the backside power rail; and
a second frontside source/drain contact disposed on a top surface of the second frontside source/drain region;
wherein the second dielectric stack comprises a first dielectric layer and a second dielectric layer.

17. The semiconductor structure of claim 15, wherein the via-to-backside power rail comprises a lower portion located on the backside power rail and an upper portion located on the sidewall of the first frontside source/drain region.

18. The semiconductor structure of claim 17, wherein the lower portion of the via-to-backside power rail comprises a step-wise configuration.

19. The semiconductor structure of claim 15, wherein the first dielectric layer comprises a first dielectric material and the second dielectric layer comprises a second dielectric material different from the first dielectric material.

20. A semiconductor structure, comprising:
a backside source/drain contact disposed on a bottom surface of a first frontside source/drain region;
a backside power rail disposed on the backside source/drain contact and separated from the first frontside source/drain region;
a second frontside source/drain region adjacent the first frontside source/drain region; and
a dielectric stack disposed on a bottom surface of the second frontside source/drain region;
wherein the dielectric stack comprises a first dielectric layer and a second dielectric layer.

21. The semiconductor structure of claim 20, wherein the backside power rail is connected to the backside source/drain contact from a backside of the semiconductor structure.

22. The semiconductor structure of claim 20, wherein an upper surface of the backside source/drain contact has a step-wise configuration comprising a top portion in contact with the first frontside source/drain region and a bottom portion extending between the first frontside source/drain region and the second frontside source/drain region.

23. The semiconductor structure of claim 20, further comprising a frontside source/drain contact disposed on a top surface of the second frontside source/drain region.

24. The semiconductor structure of claim 20, wherein the first dielectric layer comprises a first dielectric material and the second dielectric layer comprises a second dielectric material different from the first dielectric material.

25. A semiconductor device, comprising:
a first nanosheet field effect transistor device comprising a first nanosheet stack, a first gate and a first source/drain region;
a second nanosheet field effect transistor device adjacent to the first nanosheet field effect transistor device, the second nanosheet field effect transistor device comprising a second nanosheet stack, a second gate and a source/drain region;
a first dielectric stack disposed on a bottom surface of the first nanosheet field effect transistor device;
a second dielectric stack disposed on a bottom surface of the second nanosheet field effect transistor device;
a shallow trench isolation region disposed between the first dielectric stack and the second dielectric stack; and
a backside power rail disposed on the first dielectric stack, the second dielectric stack and the shallow trench isolation region and separated from the first nanosheet field effect transistor device and the second nanosheet field effect transistor device;
wherein each of the first dielectric stack and the second dielectric stack comprises a first dielectric layer and a second dielectric layer.
